(19) United States
(12) Patent Application Publication
(10) Pub. No.: US 2026/0221717 A1
(43) Pub. Date: Jul. 30, 2026

(54) SUBMOUNT, LIGHT EMITTING DEVICE, AND METHOD FOR MANUFACTURING LIGHT EMITTING DEVICE

(71) Applicant: NICHIA CORPORATION, Anan-shi (JP)

(72) Inventor: Tomokazu SAKATA, Anan-shi (JP)

(21) Appl. No.: 19/459,990

(22) Filed: Jan. 26, 2026

(30) Foreign Application Priority Data
Jan. 27, 2025 (JP) 2025-011356

(51) Int. Cl. H01S 5/02315; H01S 5/0237

(52) U.S. Cl. CPC H01S 5/02315; H01S 5/0237

(57) ABSTRACT

A submount includes a substrate, a metal layer, and an alloy layer. The alloy layer forms an alloy region provided in at least a part of an area within less than 100 μm from a first side of the substrate, and in a part of an area at a distance of 100 μm or more from the first side, and is not provided in an area within 100 μm from a line segment of a second side having a length of at least 20% or more of a total length of the second side. The alloy layer has a first end adjacent to the first side, and a second end on an opposite side. In a cross-sectional view, a thickness of the alloy layer at the first end and its vicinity is greater than a thickness at the second end and its vicinity, which is 1.5 μm or more.

### CROSS-REFERENCE TO RELATED APPLICATION

This application claims priority to Japanese Patent Application No. 2025-011356, filed on January 27, 2025, the disclosure of which is hereby incorporated herein by reference in its entirety.

### TECHNICAL FIELD

The present disclosure relates to a submount, a light emitting device, and a method for manufacturing the light emitting device.

### BACKGROUND

WO2021/261253A1 discloses a disclosure aimed at providing a semiconductor laser device in which the adhesion of bonding material to the lateral surface of a semiconductor laser element can be suppressed. In the semiconductor laser device disclosed in this document, the bonding material for joining the semiconductor laser element to the submount has an internal region that joins with the semiconductor laser element, and an external region disposed outside the internal region, with the width of the external region being adjusted.

### SUMMARY

The disclosure herein can provide a submount that can achieve a stable bonding state.

Alternatively, in place of the above measure, the disclosure herein can provide a light emitting device in which the semiconductor laser element is stably bonded to the submount.

Alternatively, in place of each of the above measures, the disclosure herein can achieve a light emitting device in which more light emitting elements can be disposed.

Alternatively, in place of each of the above measures, the disclosure can achieve a compact light emitting device.

Alternatively, in place of each of the above problems, the disclosure disclosed herein solves the problem of realizing a light emitting device with reduced wiring resistance.

Alternatively, in place of each of the above problems, the disclosure disclosed herein solves the problem of improving the output characteristics of the light emitting device.

It should be noted that in this specification, disclosures that solve a plurality of the above problems in combination are also disclosed.

The submount disclosed in the embodiment includes a substrate, a metal layer provided on an upper surface side of the substrate, and an alloy layer provided on the metal layer. An upper surface of the substrate has a first side and a second side each constituting a part of an outer edge of the substrate in a top view, the second side being opposite the first side. The alloy layer forms at least one continuous alloy region in the top view. The at least one alloy region is provided in at least a part of an area within less than 100 μm from the first side of the substrate, and in a part of an area at a distance of 100 μm or more from the first side of the substrate, and is not provided in an area within 100 μm from a line segment of the second side. The line segment having a length of at least 20% or more of a total length of the second side. The alloy layer has a first end adjacent to the first side of the substrate, and a second end on an opposite side of the first end. In a cross-sectional view taken along a plane passing through the first side of the substrate, the second side of the substrate, and the alloy region in an area where the alloy region is not provided within 100 μm from the line segment of the second side, a thickness of the alloy layer at the first end and its vicinity is greater than a thickness of the alloy layer at the second end and its vicinity. The thickness of the alloy layer at the second end and its vicinity is 1.5 μm or more.

The light emitting device disclosed in the embodiment is manufactured by placing a semiconductor laser element on the alloy layer of the above submount in a molten state and bonding the semiconductor laser element to the submount.

The light emitting device disclosed in the embodiment includes A light emitting device includes one or plurality of submounts each having an upper surface and a lower surface, one or plurality of semiconductor laser elements bonded to the one or more of submounts, and a base on which the one or plurality of submounts are mounted. Each of the one or plurality of submounts includes a substrate, a metal layer provided on the substrate, and an alloy layer provided on the metal layer. The upper surface of each of the one or plurality of submounts has a first side and a second side, each constituting a part of an outer edge of the one or plurality of submounts in a top view, the second side being opposite the first side. The alloy layer forms at least one continuous alloy region in the top view. The at least one alloy region is provided in at least a part of an area within less than 100 μm from the first side, and in a part of an area at a distance of 100 μm or more from the first side, and is not provided in an area within 100 μm from a line segment the second side, the line segment having a length of at least 20% or more of a total length of the second side. The one or plurality of semiconductor laser elements are disposed on the alloy region and bonded to the one or plurality of submounts via the alloy layer. The alloy layer has a first end adjacent to the first side, a second end on an opposite side of the first end, a first protruding portion positioned between the first end and a corresponding one of the one or plurality of semiconductor laser elements, and a second protruding portion positioned between the second end and the corresponding one of the one or plurality of semiconductor laser element. In a cross-sectional view taken along a plane passing through the first side, the second side, and the alloy region in an area where the alloy region is not provided within 100 μm from the line segment of the second side, a maximum thickness of the first protruding portion is greater than a maximum thickness of the second protruding portion.

In at least one of the one or plurality of disclosures disclosed by the embodiments, it is possible to provide a submount that can achieve a stable bonding state. Alternatively, it is possible to provide a light emitting device in which the semiconductor laser element is stably bonded to the submount.

### BRIEF DESCRIPTION OF THE DRAWINGS

FIG. 1 is a perspective view of the light emitting device according to the embodiment.

FIG. 2 is a top view of the light emitting device according to the embodiment.

FIG. 3 is a lateral side view of the light emitting device according to the embodiment.

FIG. 4 is a sectional view of the light emitting device according to the embodiment taken along line IV-IV of FIG. 2.

FIG. 5 is a perspective view for explaining components disposed inside the package of the light emitting device according to the embodiment.

FIG. 6 is a top view for explaining components disposed inside the package of the light emitting device according to the embodiment.

FIG. 7 is a perspective view of the package according to the embodiment.

FIG. 8 is a top view of the package according to the embodiment.

FIG. 9 is a sectional view of the package according to the embodiment taken along line IX-IX of FIG. 8.

FIG. 10 is a sectional view of the package according to the embodiment taken along line X-X of FIG. 8.

FIG. 11 is a top view of the base according to the embodiment.

FIG. 12 is a bottom view of the base according to the embodiment.

FIG. 13 is a sectional view of the base according to the embodiment taken along line XIII-XIII of FIG. 11.

FIG. 14 is a top view of the submount according to the embodiment with the semiconductor laser element disposed thereon.

FIG. 15 is a lateral side view of the submount according to the embodiment with the semiconductor laser element disposed thereon.

FIG. 16 is a top view of the submount according to the embodiment.

FIG. 17A is a partially enlarged sectional view of the submount according to the embodiment taken along line XVIIA-XVIIA of FIG. 16.

FIG. 17B is a schematic diagram of a submount of a reference example.

FIG. 18A is an optical microscope image of the upper surface of the submount of the example.

FIG. 18B is an optical microscope image showing the results of a heating experiment on the submount of the example.

FIG. 18C is a scanning electron microscope image of the cross-section of the submount of the example.

FIG. 18D is an enlarged image corresponding to the area A in FIG. 18C of the submount of the example.

FIG. 18E is an enlarged image corresponding to the area B in FIG. 18C of the submount of the example.

FIG. 18F is an enlarged image corresponding to the area C in FIG. 18C of the submount of the example.

FIG. 19A is an optical microscope image of the upper surface of the submount of the comparative example.

FIG. 19B is an optical microscope image showing the results of a heating experiment on the submount of the comparative example.

FIG. 19C is a scanning electron microscope image of the cross-section of the submount of the comparative example.

FIG. 19D is an enlarged image corresponding to the area A in FIG. 19C of the submount of the comparative example.

FIG. 19E is an enlarged image corresponding to the area B in FIG. 19C of the submount of the comparative example.

FIG. 19F is an enlarged image corresponding to the area C in FIG. 19C of the submount of the comparative example.

FIG. 20A is an optical microscope image of the upper surface of the submount of the reference example.

FIG. 20B is an optical microscope image showing the results of a heating experiment on the submount of the reference example.

FIG. 20C is a scanning electron microscope image of the cross-section of the submount of the reference example.

FIG. 20D is an enlarged image corresponding to the area A in FIG. 20C of the submount of the reference example.

FIG. 20E is an enlarged image corresponding to the area B in FIG. 20C of the submount of the reference example.

FIG. 20F is an enlarged image corresponding to the area C in FIG. 20C of the submount of the reference example.

FIG. 21A is a scanning electron microscope image of the cross-section of the submount with the semiconductor laser element bonded thereto in the example.

FIG. 21B is an enlarged image corresponding to the area A in FIG. 21A of the submount with the semiconductor laser element bonded thereto in the example.

FIG. 21C is an enlarged image corresponding to the area B in FIG. 21A of the submount with the semiconductor laser element bonded thereto in the example.

FIG. 21D is an enlarged image corresponding to the area C in FIG. 21A of the submount with the semiconductor laser element bonded thereto in the example.

FIG. 22A is a scanning electron microscope image of the cross-section of the submount with the semiconductor laser element bonded thereto in the comparative example.

FIG. 22B is an enlarged image corresponding to the area A in FIG. 22A of the submount with the semiconductor laser element bonded thereto in the comparative example.

FIG. 22C is an enlarged image corresponding to the area B in FIG. 22A of the submount with the semiconductor laser element bonded thereto in the comparative example.

FIG. 22D is an enlarged image corresponding to the area C in FIG. 22A of the submount with the semiconductor laser element bonded thereto in the comparative example.

FIG. 23A is a first optical microscope image showing the bonding surface of the semiconductor laser element removed from the submount of the example.

FIG. 23B is a second optical microscope image showing the bonding surface of the semiconductor laser element removed from the submount of the example.

FIG. 24A is a first optical microscope image showing the bonding surface of the semiconductor laser element removed from the submount of the comparative example.

FIG. 24B is a second optical microscope image showing the bonding surface of the semiconductor laser element removed from the submount of the comparative example.

FIG. 24C is a third optical microscope image showing the bonding surface of the semiconductor laser element removed from the submount of the comparative example.

FIG. 24D is a fourth optical microscope image showing the bonding surface of the semiconductor laser element removed from the submount of the comparative example.

### DETAILED DESCRIPTION

In this specification or the claims, regarding polygons such as triangles and quadrilaterals, shapes in which processing such as corner rounding, chamfering, edge cutting, or rounding is applied to the corners of polygons are also referred to as polygons. Similarly, shapes in which processing is applied not only to corners (ends of sides) but also to intermediate portions of sides are referred to as polygons. That is, shapes based on polygons with partial processing applied are included in the interpretation of “polygon” as described in this specification and the claims.

Similarly, not limited to polygons, the same applies to terms representing specific shapes such as trapezoids, circles, or protrusions and recessed portionions. The same also applies when dealing with each side forming the shape. That is, even if processing is applied to a corner or intermediate portion of a certain side, the processed portion is included in the interpretation of “side”. When distinguishing “polygon” or “side” without partial processing from processed shapes, the term “strict” is added, such as “strict quadrilateral”, for example.

Further, in this specification or the claims, descriptions such as up/down, upper/lower, above/below, upward /downward, left/right, front/back, front/rear, forward/rearward, in front/in the back,, etc., merely refer to relative positions, orientations, or directions, and does not have to coincide with their relationships during use. The term “on” in the present disclosure encompasses both a configuration in which a member is disposed directly on and in contact with another member and a configuration in which a member is disposed on another member with a space or an intervening member interposed therebetween. Also, the term “cover” in the present disclosure encompasses both a configuration in which a member directly covers and in contact with another member and a configuration in which a member covers another member with a space or an intervening member interposed therebetween.

In the drawings, directions such as X direction, Y direction, and Z direction may be indicated using arrows. The directions of these arrows are consistent across multiple drawings relating to the same embodiment. In addition, in the drawings, the direction of the arrow marked X, Y, or Z is defined as the positive direction, and the opposite direction is defined as the negative direction. For example, the direction in which the tip of the arrow is marked with X is the X direction and is the positive direction. In this specification, the direction that is the X direction and is the positive direction is referred to as “positive X direction”, and the opposite direction is referred to as “negative X direction”. When referring to “X direction”, both positive and negative directions are included. The same applies to Y direction and Z direction.

In this specification, when a subject is described as being “one or plurality of,” both embodiments having one such subject and embodiments having a plurality of such subjects are collectively described. Therefore, the description specifying "one or plurality of" supports embodiments having one or plurality of subjects, embodiments having at least one subject, and embodiments having a plurality of subjects.

In this specification, when describing a subject as “one or each,” such description collectively covers the case of describing one subject in an embodiment having one subject, the case of describing one subject in an embodiment having a plurality of subjects, and the case of describing each of a plurality of subjects in an embodiment having a plurality of subjects. Therefore, the description of "one or each" supports the case in which the one subject in an embodiment having one subject has the described content, the case in which at least one of the subjects in an embodiment having a plurality of subjects has the described content, the case in which each of a plurality of subjects in an embodiment having a plurality of subjects has the described content, and the case in which all of the subjects in an embodiment having one or plurality of subjects have the described content.

In this specification, when describing components or the like, the terms "member" or "part" may be used. The term "member" refers to a subject that is physically handled as a single entity. A subject physically handled as a single entity can be said to be a subject treated as a single component in the manufacturing process. On the other hand, the term "part" refers to a subject that does not necessarily have to be physically handled as a single entity. For example, "part" is used when partially referring to a portion of a member or when considering a plurality of members collectively as a single subject.

It should be noted that the distinction between "member" and "part" described above does not indicate an intention to intentionally limit the scope of rights in the interpretation of the doctrine of equivalents. That is, even when a component is described as a "member" in the claims, it does not mean that the applicant recognizes it is essential to the application of the present invention that this component is physically handled as a single entity based solely on that description.

In this specification or the claims, when there are a plurality of components and each is distinguished, the prefix "first", "second" and so on may be added to distinguish the components. Moreover, the objects to be distinguished may differ between the specification and the claims. Therefore, even if a component with the same prefix as in the specification is described in the claims, the object specified by this component does not have to coincide between the specification and the claims.

For example, in the specification, when components distinguished by the prefixes "first," "second," "third," and so on are described, and when components with the prefixes "first" and "third" are described in the claims, from the viewpoint of clarity, the components may be distinguished by the prefixes "first" and "second" in the claims. In this case, the components designated as "first" and "second" in the claims refer to the components designated as "first" and "third" in the specification, respectively. This rule is not limited to components but is also applied reasonably and flexibly to other subjects.

Hereinafter, embodiments for performing the present invention will be described. Furthermore, with reference to the drawings, specific embodiments for performing the present invention will be described. However, the embodiments for performing the present invention are not limited to these specific embodiments. That is, the illustrated embodiments are not the only forms in which the present invention may be achieved. The sizes, positional relationships, and the like of the members shown in each drawing may be exaggerated for the sake of understanding.

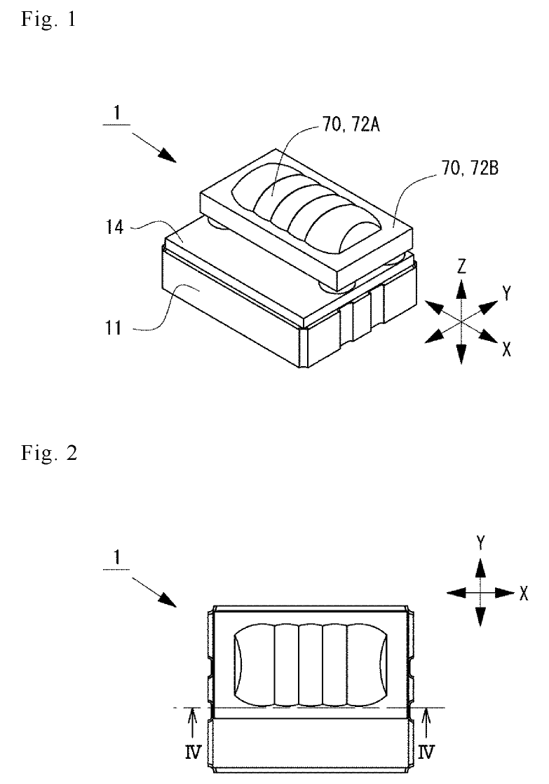

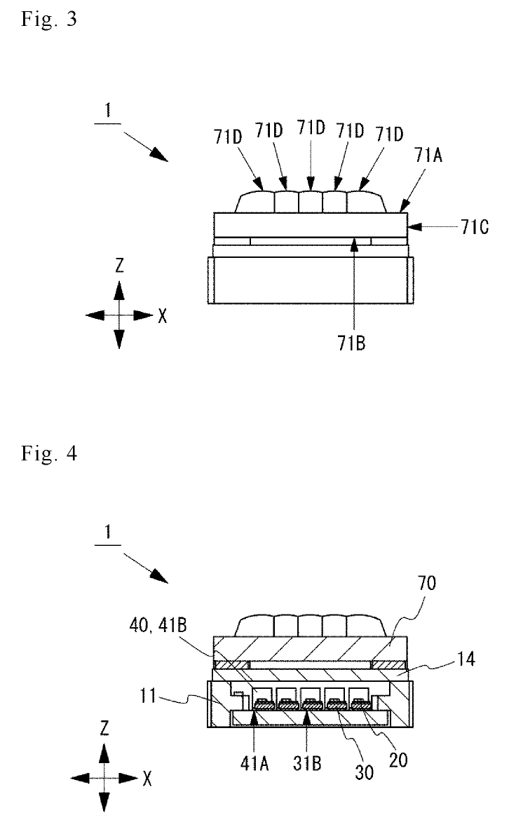

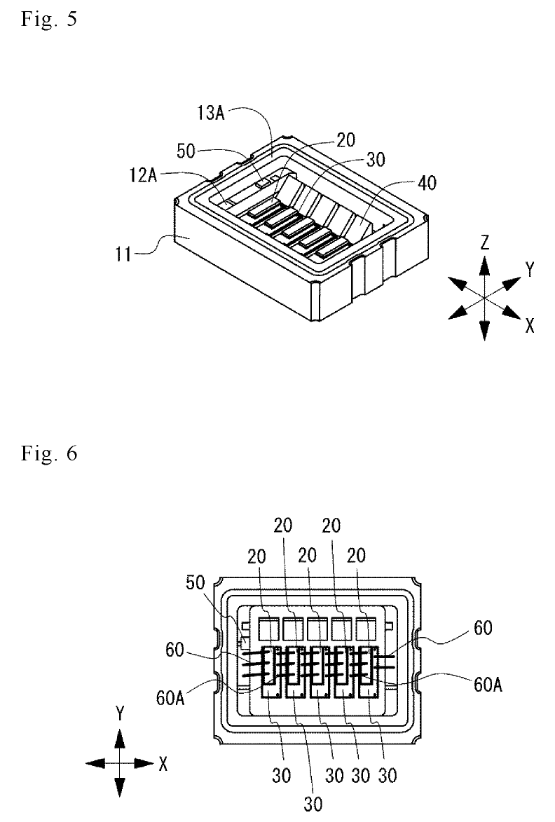

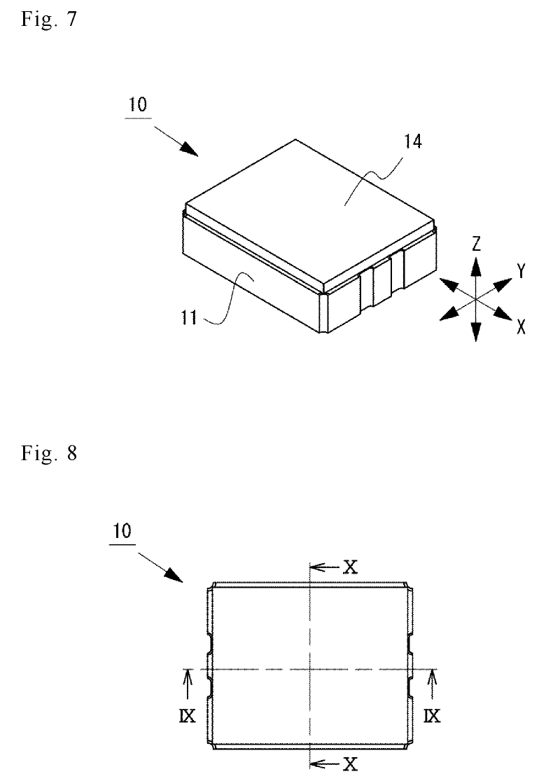

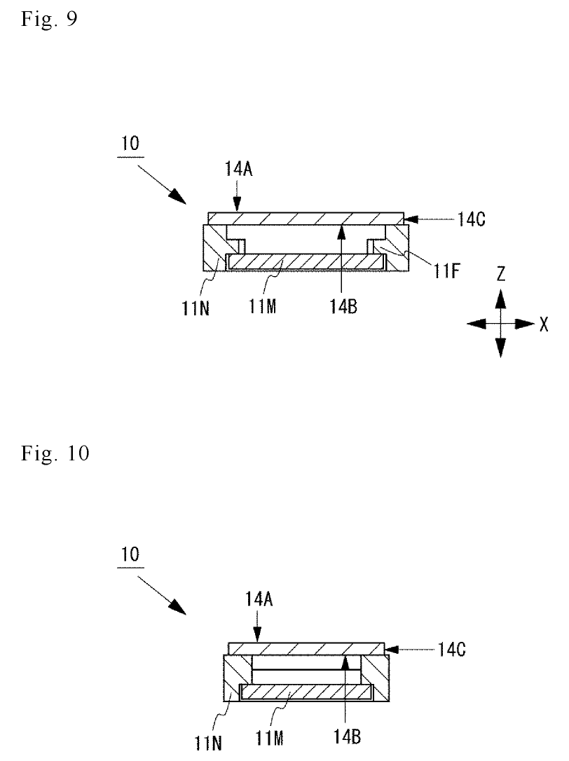

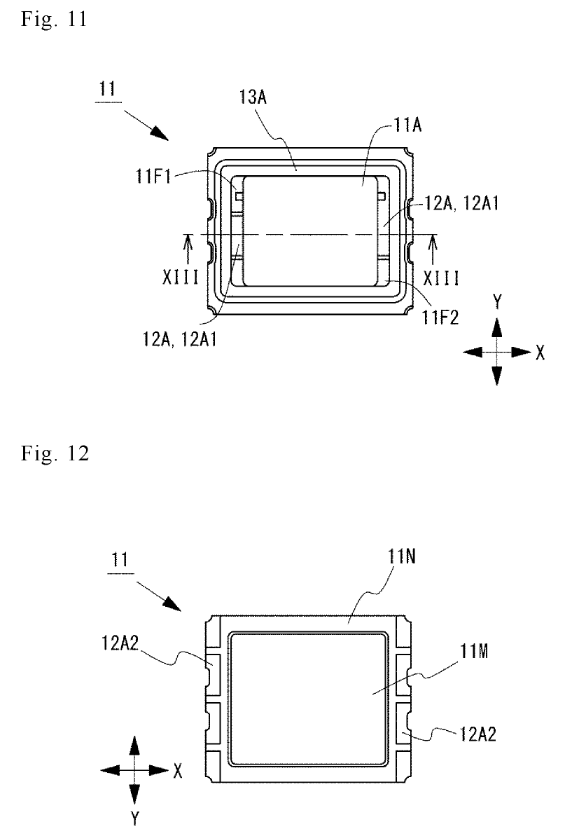

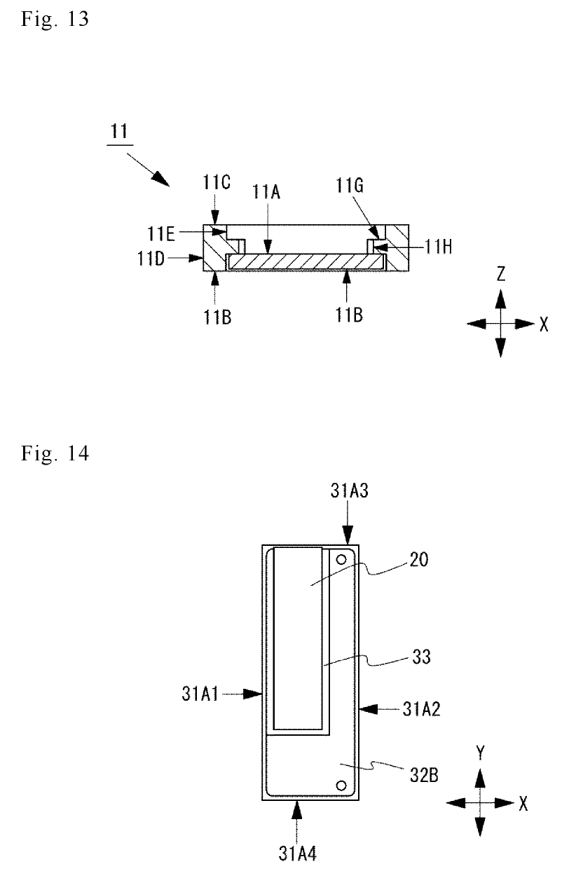

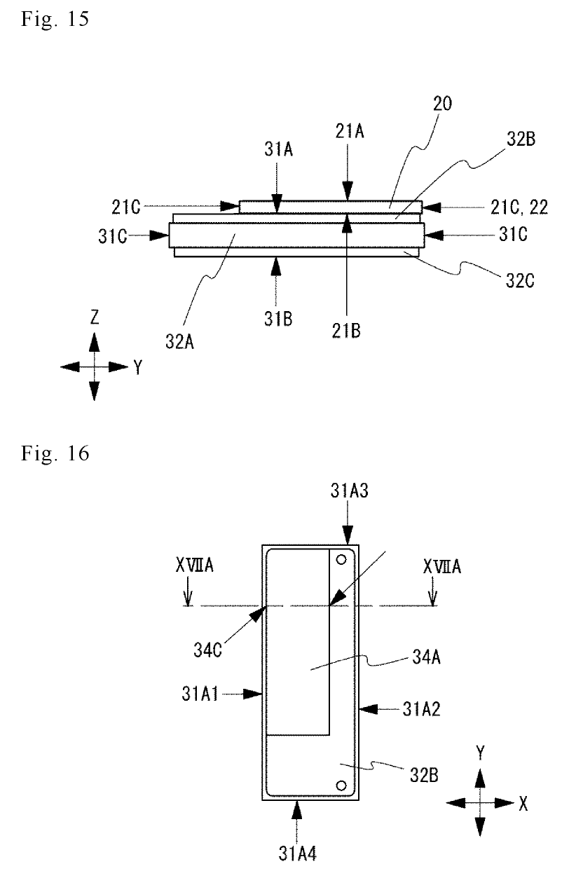

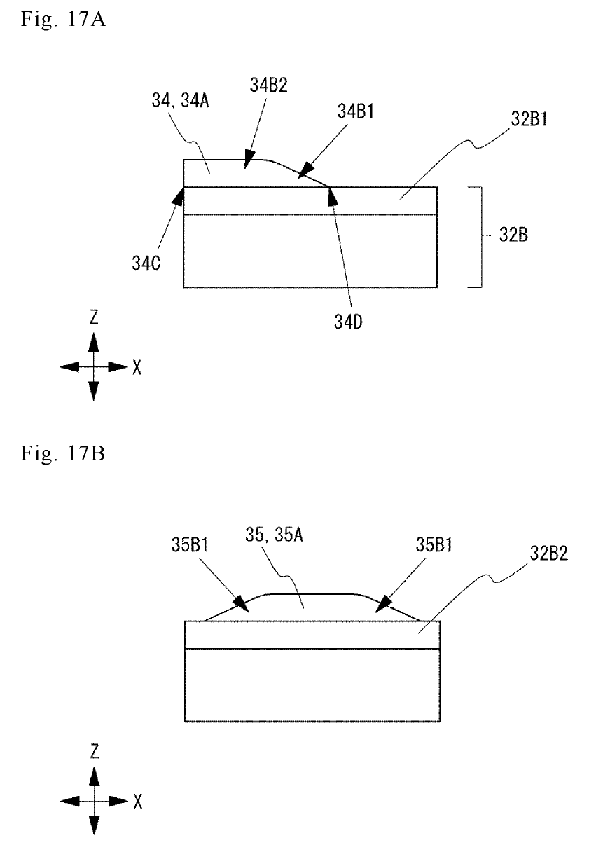

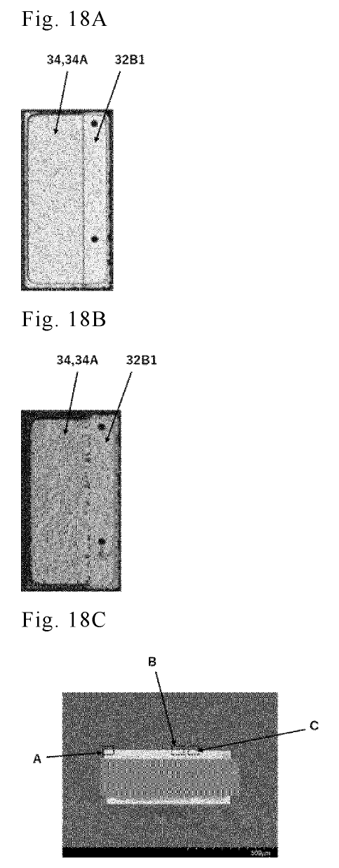

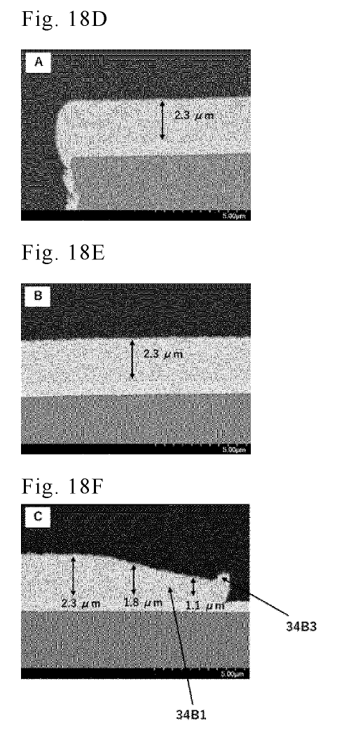

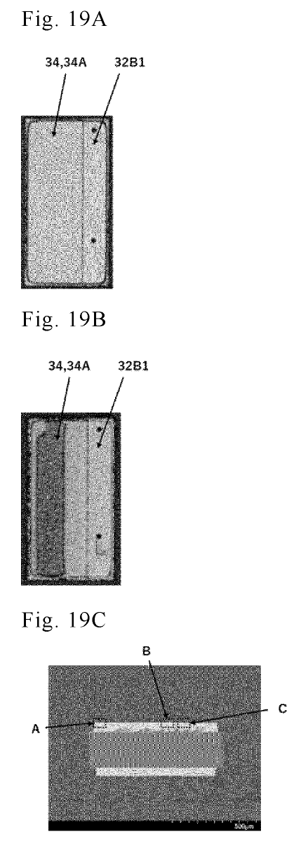

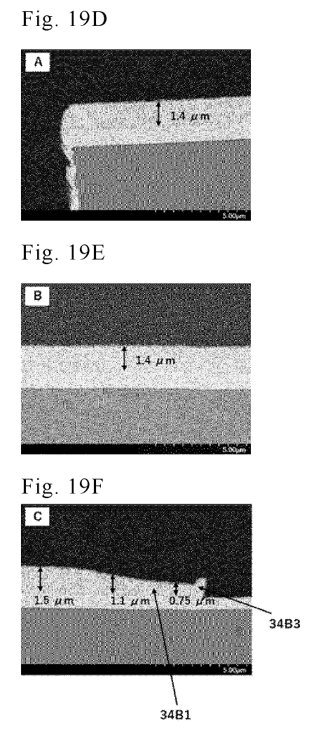

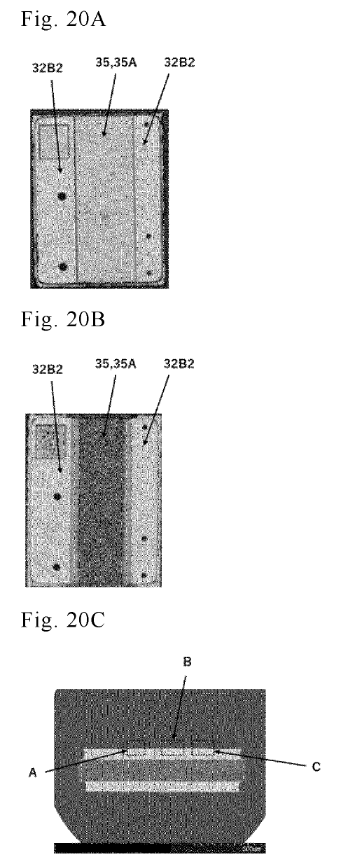

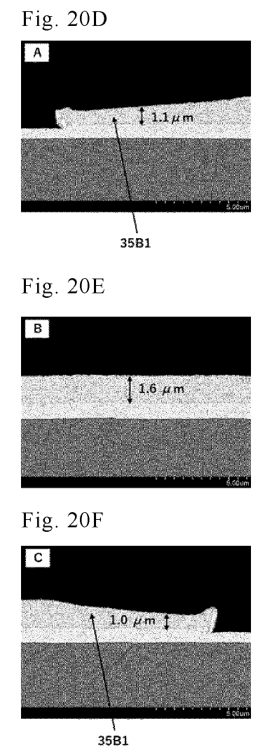

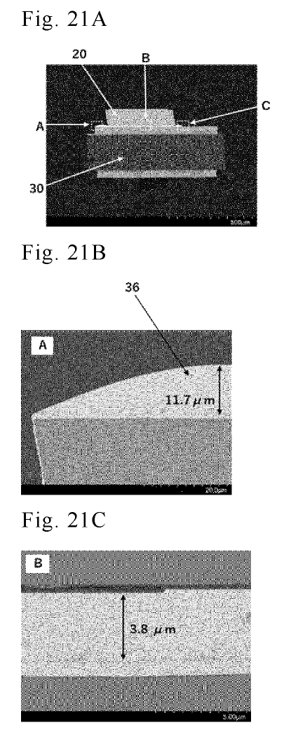

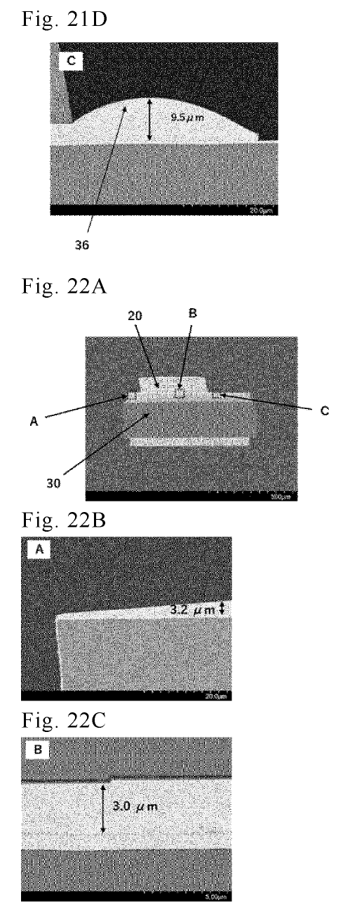

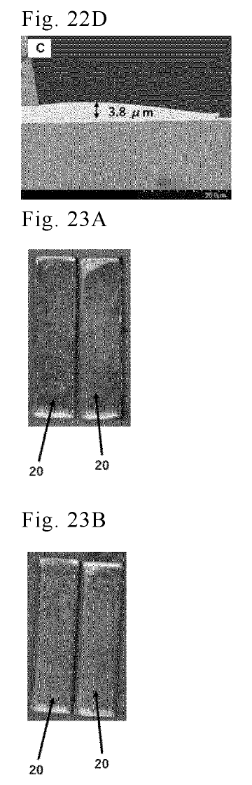

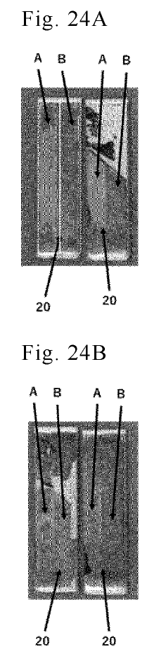

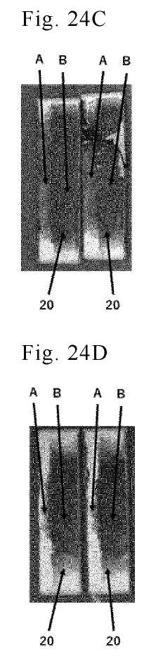

The light emitting device 1 according to the embodiment will be described. FIGS. 1 to 24D are drawings for explaining an exemplary embodiment of the light emitting device 1. FIG. 1 is a perspective view of the light emitting device 1. FIG. 2 is a top view of the light emitting device 1. FIG. 3 is a lateral side view of the light emitting device 1. FIG. 4 is a sectional view of the light emitting device 1 taken along line IV-IV of FIG. 2. FIG. 5 is a perspective view for explaining components disposed inside the package 10 of the light emitting device 1. FIG. 6 is a top view for explaining components disposed inside the package 10 of the light emitting device 1. FIG. 7 is a perspective view of the package 10. FIG. 8 is a top view of the package 10. FIG. 9 is a sectional view of the package 10 taken along line IX-IX of FIG. 8. FIG. 10 is a sectional view of the package 10 taken along line X-X of FIG. 8. FIG. 11 is a top view of the base 11. FIG. 12 is a bottom view of the base 11. FIG. 13 is a sectional view of the base 11 taken along line XIII-XIII of FIG. 11. FIG. 14 is a top view of the submount 30 with the semiconductor laser element 20 disposed thereon. FIG. 15 is a lateral side view of the submount 30 with the semiconductor laser element 20 disposed thereon. FIG. 16 is a top view of the submount 30. FIG. 17A is a partially enlarged sectional view of the submount 30 taken along line XVIIA-XVIIA of FIG. 16. FIG. 17B is a schematic diagram of a submount of a reference example. FIGS. 18A to 18F are images related to the submount of the example. FIGS. 19A to 19F are images related to the submount of the comparative example. FIGS. 20A to 20F are images related to the submount of the reference example. FIGS. 21A to 21D are images showing the state in which the semiconductor laser element is bonded to the submount of the example. FIGS. 22A to 22D are images showing the state in which the semiconductor laser element is bonded to the submount of the comparative example. FIGS. 23A and 23B are images showing the bonding surface of the semiconductor laser element removed from the submount of the example. FIGS. 24A to 24D are images showing the bonding surface of the semiconductor laser element removed from the submount of the comparative example.

The light emitting device 1 includes a plurality of components. These components include a package 10, one or plurality of semiconductor laser elements 20, one or plurality of submounts 30, one or plurality of reflecting members 40, one or more protective devices 50, a plurality of wires 60, and an optical member 70.

The light emitting device 1 may further include other components. For example, the light emitting device 1 may include, in addition to the one or plurality of semiconductor laser elements 20, further semiconductor laser elements. Furthermore, the light emitting device 1 does not have to include some of the components listed herein.

### First, each component will be described.

### Package 10

The package 10 includes a base 11 and a lid 14. The lid 14 is bonded to the base 11 to form the package 10. In the package 10, an internal space in which other components are disposed is defined. This internal space is a closed space surrounded by the base 11 and the lid 14. Further, this internal space can be a space sealed in a vacuum or airtight state.

In a top view, the outer edge shape of the package 10 is rectangular. This rectangle can have long sides and short sides. In the illustrated package 10, the long side direction of this rectangle is the same direction as the X direction, and the short side direction is the same direction as the Y direction. It should be noted that, in a top view, the outer edge shape of the package 10 does not have to be rectangular.

In the package 10, an internal space in which other components are disposed is formed. The first upper surface 11A of the package 10 is a part of the region that defines the internal space. Further, each inner lateral surface 11E and lower surface 14B of the package 10 is a part of the region that defines the internal space.

The base 11 has a first upper surface 11A and a lower surface 11B. The base 11 has a second upper surface 11C. The base 11 has one or plurality of outer lateral surfaces 11D. The base 11 has one or plurality of inner lateral surfaces 11E. The one or plurality of outer lateral surfaces 11D intersect with the second upper surface 11C. The one or plurality of outer lateral surfaces 11D intersect with the lower surface 11B. The one or plurality of inner lateral surfaces 11E intersect with the second upper surface 11C.

In a top view, the outer edge shape of the base 11 is rectangular. In a top view, the outer edge shape of the base 11 is the outer edge shape of the package 10. In a top view, the outer edge shape of the first upper surface 11A is rectangular. This rectangle can have long sides and short sides. The long side direction of the first upper surface 11A is parallel to the long side direction of the outer edge shape of the base 11. It should be noted that, in a top view, the outer edge shape of the first upper surface 11A does not have to be rectangular.

In a top view, the first upper surface 11A is surrounded by the second upper surface 11C. The second upper surface 11C is an annular surface that surrounds the first upper surface 11A in a top view. The second upper surface 11C is a rectangular annular surface. Here, the frame defined by the inner edge of the second upper surface 11C is referred to as the inner frame of the second upper surface 11C, and the frame defined by the outer edge of the second upper surface 11C is referred to as the outer frame of the second upper surface 11C.

The base 11 has a recessed portion surrounded by the frame of the second upper surface 11C. The recessed portion defines a portion that is recessed below the second upper surface 11C in the base 11. The first upper surface 11A is a part of the recessed portion. The one or plurality of inner lateral surfaces 11E are parts of the recessed portion. The second upper surface 11C is positioned above the first upper surface 11A.

The base 11 includes one or plurality of stepped portions 11F. The stepped portion 11F includes an upper surface 11G and a lateral surface 11H that intersects with the upper surface 11G and extends downward from the upper surface 11G. Here, the stepped portion 11F has only one upper surface 11G and one lateral surface 11H. The upper surface 11G intersects with the inner lateral surface 11E. The lateral surface 11H intersects with the first upper surface 11A.

The one or plurality of stepped portions 11F are provided inward of the inner frame of the second upper surface 11C in a top view. The one or plurality of stepped portion 11F are formed along a part or all of the inner lateral surface 11E in a top view. In the base 11, the lateral surface 11H is an inner lateral surface, but the lateral surface 11H and the inner lateral surface 11E are different surfaces. One or each inner lateral surface 11E and one or each lateral surface 11H is perpendicular to the first upper surface 11A. Here, perpendicularity allows for a tolerance of ±3 degrees.

The one or plurality of stepped portions 11F may include a first stepped portion 11F1 and a second stepped portion 11F2. The first stepped portion 11F1 and the second stepped portion 11F2 are provided at positions where their respective lateral surfaces 11H face each other. Each first stepped portion 11F1 and the second stepped portion 11F2 is provided on the short-side side of the inner frame of the second upper surface 11C.

The base 11 includes a base part 11M and a frame part 11N. The base part 11M and the frame part 11N may be members formed of different materials. The base 11 may be configured to include a base member corresponding to the base part 11M and a frame member corresponding to the frame part 11N.

The first upper surface 11A is included in the base part 11M. The second upper surface 11C is included in the frame part 11N. The frame part 11N includes one or plurality of outer lateral surfaces 11D and one or plurality of inner lateral surfaces 11E. The frame part 11N includes one or plurality of stepped portions 11F.

The lower surface of the base part 11M forms a part or all of the lower surface 11B of the base 11. When the lower surface of the base part 11M forms a part of the lower surface 11B of the base 11, the lower surface of the frame part 11N forms the remaining region of the lower surface 11B of the base.

The base 11 includes a plurality of wiring parts 12A. The plurality of wiring parts 12A include one or plurality of first wiring parts 12A1 disposed in the internal space of the package 10 and one or plurality of second wiring parts 12A pr2ovided on the outer surface of the package 10.

The one or plurality of first wiring parts 12A1 are provided on the upper surface(s) 11G of the stepped portion 11F. The base 11 includes one or plurality of first wiring parts 12A1 provided on the upper surface 11G of the first stepped portion 11F1. The base 11 includes one or plurality of first wiring parts 12A1 provided on the upper surface 11G of the second stepped portion 11F2.

The one or plurality of second wiring parts 12A2 are provided on the lower surface 11B of the package 10. The one or plurality of second wiring parts 12A2 are provided on the lower surface of the frame part 11N. It should be noted that the second wiring part 12A2 may be provided on an outer surface different from the lower surface 11B of the package 10.

In a top view, the base 11 includes one or plurality of second wiring parts 12A2 provided on the lower surface 11B of the base 11 in a region including the upper surface 11G of the first stepped portion 11F1, when the base 11 is divided into two regions by an imaginary line passing through the lateral surface 11H of the first stepped portion 11F1 and parallel to this lateral surface 11H.

In a top view, the base 11 includes one or plurality of second wiring parts 12A2 provided on the lower surface 11B of the base 11 in a region including the upper surface 11G of the second stepped portion 11F2, when the base 11 is divided into two regions by an imaginary line passing through the lateral surface 11H of the second stepped portion 11F2 and parallel to this lateral surface 11H.

In the base 11, one or each first wiring part 12A1 is electrically connected to the second wiring part 12A2. One or plurality of first wiring parts 12A1 are electrically connected to different second wiring parts 12A2.

The base 11 has a bonding pattern 13A. The bonding pattern 13A is provided on the second upper surface 11C. The bonding pattern 13A is provided in an annular shape. The bonding pattern 13A is provided in a rectangular annular shape. In a top view, the first upper surface 11A is surrounded by the bonding pattern 13A.

The base 11 can be formed using ceramic as the main material, for example. Examples of ceramics used as the main material for the base 11 can include aluminum nitride, silicon nitride, aluminum oxide, and silicon carbide.

Here, the main material refers to the material that occupies the largest proportion by mass or volume in the relevant formed object. If the object is formed from a single material, that material is the main material. That is, being the main material means that the proportion of that material can be 100%.

The base 11 may also be formed using a base member and a frame member formed from different main materials. The base member can be formed using, for example, a material with good heat dissipation as the main material, such as metal or a metal-containing composite, graphite, or diamond. A metal for use as a primary material for the base member is, for example, copper, aluminum, or iron. A composite containing a metal for use as a primary material for the base member is, for example, molybdenum copper or tungsten copper. The frame member can be formed by using as a primary material any of the ceramics listed as a primary material for the base 11 described above.

The wiring parts 12A can be formed, for example, by using a metal as a primary material. Examples of metal materials for use as a primary material for the wiring parts 12A include simple metals, such as Cu, Ag, Ni, Au, Ti, Pt, Pd, Cr, W, and the like, or alloys containing these metals. The wiring part 12Acan be configured with one or plurality of metal layers, for example.

The bonding pattern 13A can be formed using a metal material as the main material, for example. Examples of metal materials used as the main material for the bonding pattern 13A can include single metals such as Cu, Ag, Ni, Au, Sn, Ti, or Pd, or alloys containing these metal. The bonding pattern 13A can be configured with one or plurality of metal layers, for example.

The lid 14 has an upper surface 14A and a lower surface 14B. Further, the lid 14 has one or plurality of lateral surfaces 14C. The lid 14 has a flat plate shape of a rectangular parallelepiped. It should be noted that the shape of the lid 14 does not have to be a rectangular parallelepiped.

The lid 14 is joined to the base 11. The lower surface 14B of the lid 14 is joined to the second upper surface 11C of the base 11. The lid 14 is joined to the bonding pattern 13A of the base 11. The lid 14 is joined to the base 11 via an adhesive.

The lid 14 is light transmissive that allows light to pass through. Here, light transmissive means that the transmittance of light incident on the lid 14 is 80% or more. It should be noted that the lid 14 may have a region (a region without being light transmissive) that is not light transmissive in part.

The lid 14 can be formed using, for example, glass as the main material. Alternatively, the lid 14 can be formed using sapphire as the main material, for example.

### Semiconductor laser element 20

The semiconductor laser element 20 has an upper surface 21A, a lower surface 21B, and a plurality of lateral surfaces 21C. The shape of the upper surface 21A is a rectangle having long sides and short sides. The outer shape of the semiconductor laser element 20 in a top view is a rectangle having long sides and short sides. It should be noted that the shape of the upper surface 21A and the outer shape of the semiconductor laser element 20 in a top view are not limited to this.

The semiconductor laser element 20 has a light emission surface 22 that emits light. For example, a lateral surface 21C can serve as the light emission surface 22. The lateral surface 21C serving as the light emission surface 22 intersects with the short side of the upper surface 21A. Alternatively, the upper surface 21A can serve as the light emission surface 22, for example.

The semiconductor laser element 20 may be a single-emitter semiconductor laser element configured with one emitter. Alternatively, the semiconductor laser element 20 may be a multi-emitter semiconductor laser element configured with a plurality of emitters.

The semiconductor laser element 20 may be a semiconductor laser element that emits red light, for example. Alternatively, the semiconductor laser element 20 may be a semiconductor laser element that emits green light, for example. Alternatively, the semiconductor laser element 20 may be a semiconductor laser element that emits blue light, for example. It should be noted that the semiconductor laser element 20 may be a semiconductor laser element that emits light of other colors or wavelengths.

Here, blue light refers to light having a peak emission wavelength in the range of 420 nm to 494 nm. Green light refers to light having a peak emission wavelength in the range of 495 nm to 570 nm. Red light refers to light having a peak emission wavelength in the range of 605 nm to 750 nm.

As the semiconductor laser element 20 that emits blue light or green light, a semiconductor laser element including a nitride semiconductor can be used. As nitride semiconductors, GaN-based semiconductors such as GaN, InGaN, and AlGaN can be employed. As the semiconductor laser element 20 that emits red light, a semiconductor laser element including a semiconductor such as InAlGaP-based, GaInP-based, or GaAs-based semiconductors such as GaAs or AlGaAs can be used.

The semiconductor laser element 20 emits directional laser light. Divergent light having a spread is emitted from the light emission surface 22 (emission end face) of the semiconductor laser element 20. The light emitted from the semiconductor laser element 20 forms an elliptical far-field pattern (hereinafter referred to as "FFP") in a plane parallel to the light emission surface 22. FFP refers to the shape and light intensity distribution of emitted light at a position distant from the light emission surface of the semiconductor laser element.

Here, the light passing through the center of the elliptical shape of the FFP, in other words, the light at the peak intensity in the light intensity distribution of the FFP, is referred to as the light traveling along the optical axis or the light passing through the optical axis. In addition, in the light intensity distribution of the FFP, light having an intensity of 1/e^2 or more with respect to the peak intensity value is referred to as the main portion of the light.

The shape of the FFP of the light emitted from the semiconductor laser element 20 is an elliptical shape in a plane parallel to the light emission surface 22, in which the major axis is in the stacking direction and is longer than the minor axis, which is perpendicular to the stacking direction. The stacking direction is the direction in which a plurality of semiconductor layers including the active layer are stacked in the semiconductor laser element 20. The direction perpendicular to the stacking direction can also be described as the planar direction of the semiconductor layers. The major axis direction of the elliptical shape of the FFP can be referred to as the fast axis direction of the semiconductor laser element 20, and the minor axis direction can be referred to as the slow axis direction of the semiconductor laser element 20.

The angle at which the light of the 1/e² intensity of the peak light intensity in the light intensity distribution of the FFP spreads is defined as the divergence angle of the light of the semiconductor laser element 20. Here, the divergence angle of the light is indicated by the angle formed between the peak intensity light (light passing through the optical axis) and the light of 1/e² intensity of the peak light intensity. It should be noted that the divergence angle of the light may sometimes be determined from the half value of the peak light intensity in addition to the 1/e² intensity of the peak light intensity. In the explanation of this specification, when simply referring to "divergence angle of the light," it indicates the divergence angle at the 1/e² intensity of the peak light intensity.

The divergence angle of the light in the fast axis direction emitted from the semiconductor laser element 20 can be 30 degrees or more and less than 75 degrees. Further, the divergence angle of this light in the slow axis direction can be greater than 0 degrees and 20 degrees or less. Moreover, the divergence angle in the fast axis direction of this light is larger than the divergence angle in the slow axis direction.

For example, the divergence angle in the fast axis direction of blue light emitted from the semiconductor laser element 20 can be 30 degrees or more and less than 60 degrees, and the divergence angle in the slow axis direction can be 5 degrees or more and less than 20 degrees. Also for example, the divergence angle in the fast axis direction of green light emitted from the semiconductor laser element 20 can be 30 degrees or more and less than 60 degrees, and the divergence angle in the slow axis direction can be 5 degrees or more and less than 20 degrees. Also for example, the divergence angle in the fast axis direction of red light emitted from the semiconductor laser element 20 can be 40 degrees or more and less than 75 degrees, and the divergence angle in the slow axis direction can be greater than 0 degrees and less than 20 degrees.

In a top view, the width of the semiconductor laser element 20 in the direction perpendicular to the light emission surface 22 is 1000 μm or more. Further, this width can be 1500 μm or more. Further, this width can be 2000 μm or less. It should be noted that this width in the semiconductor laser element 20 is not limited to the numerical ranges described here. In the illustrated semiconductor laser element 20, the direction perpendicular to the light emission surface 22 is the same direction as the Y direction.

In a top view, the width of the semiconductor laser element 20 in the direction parallel to the light emission surface 22 is 100 μm or more. Further, this width can be 400 μm or more. Further, this width is 500 μm or less. It should be noted that this width in the semiconductor laser element 20 is not limited to the numerical ranges descibed here. In the illustrated semiconductor laser element 20, the direction parallel to the light emission surface 22 is the same direction as the X direction.

### Submount 30

The submount 30 has an upper surface 31A, a lower surface 31B, and one or plurality of lateral surfaces 31C. The upper surface 31A can be referred to as the mounting surface on which other components are mounted. The shape of the upper surface 31A is rectangular. This rectangle of the upper surface 31A can have short sides and long sides. It should be noted that the shape of the upper surface 31A does not have to be rectangular.

In a top view, the outer shape of the submount 30 is rectangular. This rectangle of the submount 30 can have short sides and long sides. It should be noted that the outer shape of the submount 30 in a top view does not have to be rectangular. In a top view, the submount 30 may have an outer shape in which the length in one direction (hereinafter, this direction is referred to as the short side direction of the submount 30) is smaller than the length in the direction perpendicular to this direction (hereinafter, this direction is referred to as the long side direction of the submount 30). In the illustrated submount 30, the short side direction is the same direction as the X direction, and the long side direction is the same direction as the Y direction.

The upper surface 31A has a first side 31A1 and a second side 31A2, each of which constitutes a part of the outer edge in a top view. The second side 31A2 is the side opposite to the first side 31A1. Moreover, the upper surface 31A has a third side 31A3 and a fourth side 31A4, each of which constitutes a part of the outer edge in a top view. The fourth side 31A4 is the side opposite to the third side 31A3. The first side 31A1 and the second side 31A2 may be the long sides, and the third side 31A3 and the fourth side 31A4 may be the short sides.

The submount 30 can be configured with a substrate 32A and an upper metal member 32B. Further, the submount 30 can be configured with a lower metal member 32C. The upper metal member 32B is provided on the upper surface side of the substrate 32A. The lower metal member 32C is provided on the lower surface side of the substrate 32A. The submount 30 further includes a wiring layer 33. The wiring layer 33 is provided on the upper metal member 32B.

In a top view, the outer shape of the wiring layer 33 is rectangular. This rectangle of the wiring layer 33 can have short sides and long sides. The short sides of the wiring layer 33 are parallel to the short side direction of the submount 30, and the long sides of the wiring layer 33 are parallel to the long side direction of the submount 30.

With respect to the short side direction of the submount 30 in a top view, the wiring layer 33 is provided closer to one of the two ends of the upper metal member 32B. The distance from the wiring layer 33 to the other of these two ends is preferably 150 μm or more. By ensuring a distance of 150 μm or more, it becomes easier to secure an area for mounting the submount 30 or for wiring on the submount 30. In a top view, a virtual straight line L parallel to the long side direction passes through the midpoint of the width of the upper surface 31A in the short side direction and passes through the wiring layer 33. In this way, the submount 30 can be designed so that the width in the short side direction becomes smaller.

With respect to the long side direction of the submount 30 in a top view, the wiring layer 33 is provided closer to one of the two ends of the upper metal member 32B. The distance from the wiring layer 33 to this one end is 0 μm or more and 50 μm or less. The distance from the wiring layer 33 to the other of these two ends can be 100 μm or more and 700 μm or less. In the illustrated submount 30, the wiring layer 33 is provided closer to the first side 31A1 and the third side 31A3.

The substrate 32A has insulation properties. The substrate 32A is formed of, for example, silicon nitride, aluminum nitride, or silicon carbide. It is preferable to select a ceramic with relatively good heat dissipation (high thermal conductivity) as the main material for the substrate 32A.

As the main material for the upper metal member 32B, a metal such as copper or aluminum is used. The upper metal member 32B includes one or plurality of metal layers. The upper metal member 32B may include a plurality of metal layers with different metals as the main materials. For example, a metal layer of Pt may be formed on the upper surface of the upper metal member 32B. Hereinafter, the metal layer constituting the upper surface of the upper metal member 32B is referred to as the metal layer 32B1.

As the main material for the lower metal member 32C, a metal such as copper or aluminum is used. The lower metal member 32C includes one or plurality of metal layers. The lower metal member 32C may include a plurality of metal layers with different metals as the main materials.

The wiring layer 33 can employ an alloy layer. For the alloy layer, for example, an alloy layer of AuSn such as AuSn solder can be used. It should be noted that the alloy forming the alloy layer is not limited to AuSn, and, for example, the use of AgSn or CuSn may also be considered. Hereinafter, when specifying the wiring layer 33 as an alloy layer, it will be referred to as the alloy layer 34 instead of the wiring layer 33.

For example, the length of the submount 30 in the short side direction or short-length direction is 500 μm or more and 850 μm or less. Further, the length of the submount 30 in the long side direction or long-length direction is 1500 μm or more and 2700 μm or less. Further, the difference between the length in the long-length direction and the short-length direction of the submount 30 is 1000 μm or more and 2000 μm or less.

For example, the thickness of the submount 30 (the length in the direction perpendicular to the upper surface 31A) is 200 μm or more and 400 μm or less. Also for example, the thickness of the substrate 32A is 100 μm or more and 300 μm or less. Also for example, the thickness of the upper metal member 32B is 5 μm or more and 80 μm or less. Also for example, the thickness of the lower metal member 32C is 5 μm or more and 80 μm or less.

The width of the wiring layer 33 in the short side direction or short-length direction of the submount 30 can be 250 μm or more and 700 μm or less. The width of the wiring layer 33 in the long side direction or long-length direction of the submount 30 can be 1200 μm or more and 2700 μm or less. Also for example, the thickness of the wiring layer 33 is 1.0 μm or more and 5.0 μm or less.

Here, the shape of the alloy layer 34 when the alloy layer 34 is provided on the metal layer 32B1 will be described. For easier comparison of shapes, a reference example of a submount of another form in which an alloy layer is provided on a metal layer is shown in FIG. 17B. In the other form of the submount (reference example submount) in FIG. 17B, the reference example submount includes a metal layer 32B2, an alloy layer 35, and an alloy region 35A.

The alloy layer 34 forms a single continuous alloy region 34A in a top view. The alloy layer 34 forms at least one alloy region 34A. In a top view, a plurality of alloy regions 34A that are separated from each other may be formed.

When the metal layer 32B1 extends beyond the outside of the alloy region 34A in a top view, a thinning region 34B1, in which the alloy layer 34 gradually becomes thinner due to the influence of the metal layer 32B1, may be formed at the end of the alloy region 34A. The formation of a thinning region also applies to submounts of other forms, and when the metal layer 32B2 extends on both sides of the alloy region 35A of the alloy layer 35, thinning regions 35B1 may be formed at both ends of the alloy region 35A.

As in the submount 30, when the wiring layer 33 is located close to one end and apart from the other end, as shown in the drawings, a thinning region 34B1 may be formed only on the side of the other end among both ends of the wiring layer 33. Further, the alloy region 34A has a flat region 34B2, where the alloy layer 34 is formed with a constant thickness, in comparison to the thinning region 34B1.

A wiring layer 33 formed from an alloy of two or more metals, like the alloy layer 34, may provide more advantageous effects than a wiring layer formed from a single metal. For example, during bonding processing, AuSn solder can secure a longer melting time than Sn solder without containing Au. This melting time changes depending on how much Au is present around Sn in the wiring layer 33, and if sufficient Au is present, a long melting time can be secured. Therefore, when an alloy layer of AuSn solder is formed with a thinning region, there may be cases where the melting time is insufficient due to the thinning region being too thin.

Also, whether thinning regions are present on both sides of the alloy layer 34 or only on one side can affect the melting time. For example, a case having a thinning region only on one side may result in a shorter melting time of the alloy layer 34 than in a case having thinning regions on both sides.

Thus, it is necessary to set an appropriate design thickness in consideration of the shape of the wiring layer 33 in the thickness direction. Here, the meaning of "design" is that it is generally difficult to precisely control the thickness at a specific position of the thinning region, and it can be considered that the thickness of the region that is not the thinning region (flat region) becomes the target thickness in manufacturing, in other words, the design thickness. That is, it is desirable to set the design thickness in order to secure sufficient thickness in the thinning region.

For example, even if the design thickness of the alloy region is the same (for example, 1.5 μm) in the case where a semiconductor laser element with a width of 400 μm is bonded to a submount in which a metal layer extends on both sides of an alloy region with a width of 520 μm, and in the case where a semiconductor laser element with a width of 400 μm is bonded to a submount in which a metal layer extends only on one side of an alloy region with a width of 520 μm, stable bonding can be obtained in the former submount, while stable bonding may not be obtained in the latter submount.

FIGS. 18A to 20F are images showing experimental results of observing the state of the alloy layer when a metal layer constituting the upper surface of the upper metal member 32B is Pt and an alloy layer of AuSn solder is formed on this metal layer. FIGS. 18A to 18F show an example, FIGS. 19A to 19F show a comparative example, and FIGS. 20A to 20F show a reference example.

Here, the reference example refers to an example corresponding to a reference example submount having thinning regions on both sides. In addition, the example and the comparative example are classified based on a comparison with the reference example submount, with those having a smaller thickness in the thinning region as the comparative example, and those having an equal or greater thickness as the example. For example, while some documents distinguish between example and comparative example based on novelty, in this specification, the classifications of example, comparative example, and reference example do not have any meaning other than the above description. Moreover, in relation to one invention, the example and comparative example may be classified according to whether they are effective for the problem of the invention, but for another invention, both the example and the comparative example may be effective for the problem of this other invention.

FIG. 18A shows the state in a top view at the stage of forming the alloy layer. FIG. 18B shows the state in a top view after heating the formed alloy layer in FIG. 18A at 320°C for 2 seconds and then cooling to room temperature. The same applies to FIGS. 19A and 19B, as well as FIGS. 20A and 20B.

The letters A to C displayed in the corners of the images in FIGS. 18D to 18F indicate that these are enlarged images corresponding to the frames A to C shown in FIG. 18C. The same applies to FIGS. 19D to 19F and FIG. 19C, and to FIGS. 20D to 20F and FIG. 20C.

In the example, the alloy layer is provided close to one side, and the design thickness of the alloy layer is 2.5 μm. In the comparative example, the alloy layer is provided close to one side, and the design thickness of the alloy layer is 1.5 μm. In the reference example, the alloy layer is provided without being close to one side, and the design thickness of the alloy layer is 1.5 μm.

Comparing the comparative example and the reference example, the design thickness of the alloy layer is 1.5 μm in both cases, but as shown in the images of FIGS. 19F and 20F, the minimum thickness in the thinning region 34B1 of the comparative example is about 0.75 μm, while the minimum thickness in the thinning region 35B1 of the reference example is about 1.0 μm. Thus, even if the design thickness of the alloy layer is the same, a difference in the minimum thickness of the thinning region can occur depending on whether the thinning region is formed on only one side or on both sides.

Moreover, as shown in the images of FIGS. 19B and 20B, due to this difference in thickness, the state of the alloy layer heated under the same temperature and for the same time also differs. In both alloy layers, a clear distinction between hardened and molten states can be seen, but the degree is different. The darker part at the center of the alloy layer is in the molten state at the time of heating stop, and the lighter part on the outside is in the hardened state at the time of heating stop, which is considered to result in this bipolarization. The alloy layer becomes hardened after being in a molten state, and if a component is mounted on the hardened alloy layer, bonding becomes insufficient, but in the comparative example, the hardening from the thinning region is more promoted than in the reference example, and the hardened region is expanded.

Comparing the example and the reference example, as shown in FIG. 18F and FIGS. 20D and 20F, the minimum thickness in the thinning region in the example submount can be made equal to or greater than the minimum thickness in the thinning region in the reference example submount. Thus, an alloy layer where a thinning region is formed only on one side can achieve uniform minimum thickness condition by increasing the design thickness compared to an alloy layer where thinning regions are formed on both sides. As shown in the image of FIG. 18B, in the example submount, bipolarization between hardened and molten states is hardly progressed, and almost the entire alloy layer can maintain the molten state.

As described above, by considering the arrangement of the alloy layer 34 on the submount 30 and appropriately adjusting the thickness, it is possible to secure sufficient melting time and achieve a stable bonding state with other components. As an example, the guideline for sufficient melting time is 5 seconds or more, but it is to be appropriately set according to the manufacturing process. If a longer melting time can be secured, bonding of the alloy layer to the submount 30 becomes easier.

For example, when bonding a light emitting element such as the semiconductor laser element 20 to the submount 30, there may be a desire to reduce the size of the submount 30 to arrange more light emitting elements in a predetermined space, and for that purpose, the alloy layer may be provided closer to one side of the upper surface 31A of the submount 30. In such a case, by forming the alloy layer 34 with an appropriate thickness, it is possible to achieve a light emitting device in which the light emitting element is stably bonded to the submount.

When a single continuous alloy region 34A is provided on the metal layer 32B1 in a region within less than 100 μm from the first side 31A1, in a region in the range of 100 μm or more from the first side 31A1, and is not provided in a region within 100 μm from the second side 31A2, then, in a cross-sectional view, determining the end of the alloy region 34A on the first side 31A1 side is taken as the first end 34C and the end of the alloy region 34A on the second side 31A2 side is taken as the second end 34D, it is preferable that the thickness of the alloy layer 34 at the second end 34D and its vicinity is 1.5 μm or more. Further, the thickness of the alloy layer 34 at the first end 34C and its vicinity is greater than the thickness of the alloy layer 34 in at the second end 34D and its vicinity. By forming such an alloy layer 34, the submount 30 can achieve a stable bonding state. Here, the cross-sectional view is a cross-sectional view passing through the first side 31A1, the second side 31A2, and the alloy region 34A.

It should be noted that the thickness of the alloy layer 34 at the end and its vicinity may not necessarily form a shape in which the alloy layer 34 rises neatly and vertically at the end as in the first end in FIG. 17A (see also FIG. 18D, etc.), and in such cases, consideration is given to the fact that, theoretically, the thickness at the end may become zero. For example, the thickness of the end and its vicinity may be the maximum thickness within a range of several μm from the end. Also for example, the thickness at the end and its vicinity may be the maximum thickness within a range of 5.0 μm from the end.

Such consideration also applies to the thinning region 34B1. When the end of the alloy layer 34 does not rise neatly and vertically, the end can become relatively thinner, and if the concept is extended to the maximum, it is not impossible to interpret this as "thinning," but such a state is not intended. On the first end 34C side, there is no region in which the thickness decreases toward the first end 34Cin a similar and/or equivalent to the thinning region 34B1 formed on the second end 34D side.

The alloy region 34A has, in a cross-sectional view, a thinning region 34B1 on the second end 34D side, in which the thickness decreases toward the second end 34D. In a cross-sectional view, the thinning region 34B1 is formed on the second end 34D side with a length of 3 μm or more. In a cross-sectional view, a thinning region may be formed on the first end 34C side with a length of 0 μm or more and less than 3 μm. Here, a thinning region length of 0 μm means that the thinning region is not substantially formed.

It is not essential for the alloy region 34A to be provided in all of the area within less than 100 μm from the first side 31A1 in a top view; it is provided in at least a part of this area. Similarly, it is not essential for the alloy region 34A to be absent in all of the area within 100 μm from the second side 31A2 in a top view; it is absent in at least a part of this area.

The alloy region 34A is not provided in an area within 100 μm from a line segment of at least 20% or more of the total length of the second side 31A2. Alternatively, the alloy region 34A is not provided in an area within 100 μm from a line segment of at least 50% or more of the total length of the second side 31A2. In the illustrated light emitting device 1, the alloy region 34A is not provided in all of the area within 100 μm from the second side 31A2.

The maximum thickness of the alloy layer 34 where the alloy region 34A is formed is 2.0 μm or more. Further, the maximum thickness of the alloy layer 34 where the alloy region 34A is formed can be 5.0 μm or less. Alternatively, the maximum thickness of the alloy layer 34 where the alloy region 34A is formed can be 3.5 μm or less. The maximum thickness can be equal to the design thickness, and thus, the value of the maximum thickness can affect the melting time. It should be noted that the maximum thickness of the alloy layer 34 here is determined excluding alloy layers 34 that are separated from the alloy region 34A.

In the submount 30, the difference between the maximum thickness and the minimum thickness in the thinning region 34B1 is 0.7 μm or more. Further, this difference can be 0.9 μm or more, and even 1.1 μm or more. As shown in the images of FIGS. 19F and 20F, the difference between the maximum thickness and the minimum thickness in the reference example submount is about 0.6 μm, and the difference between the maximum thickness and the minimum thickness in the comparative example submount is about 0.75 μm. In the example submount, the difference between the maximum thickness and the minimum thickness becomes larger than that in the comparative example submount or reference example submount.

As shown in the images of FIGS. 18F and 19F, the submount may have a thickened region 34B3 between the thinning region and the end on the thinning region 34B1 side. For example, when the thinning region 34B1 is formed on the second end 34D side, the alloy layer 34 includes a thickened region 34B3 between the thinning region 34B1 and the second end 34D while being on the second end 34D side in a cross-sectional view. The thickness of the thickened region 34B3 is greater than the minimum thickness of the thinning region 34B1. As shown in the images of FIGS. 20D and 20F, a thickened region may also be formed in the reference example submount.

By forming a thickened region 34B3 between the thinning region 34B1 and the end, it is considered that the transition of the thinning region 34B1 to the hardened state can be delayed, making it easier to maintain the molten state.

### Reflecting member 40

The reflecting member 40 has a lower surface 41A and a light reflecting surface 41B that reflects light. Further, the light reflecting surface 41B is inclined with respect to the lower surface 41A. A straight line connecting the lower end and upper end of the light reflecting surface 41B is inclined with respect to the lower surface 41A. The angle at which the light reflecting surface 41B is inclined with respect to the lower surface 41A is referred to as the inclination angle of the light reflecting surface 41B.

The light reflecting surface 41B is a flat surface. It should be noted that the light reflecting surface 41B may be a curved surface. The inclination angle of the light reflecting surface 41B is 45 degrees. It should be noted that the inclination angle of the light reflecting surface 41B does not have to be 45 degrees.

As the main material of the reflecting member 40, glass or metal may be used. It is preferable to use a material resistant to heat as the main material of the reflecting member 40. As the main material, for example, glass such as quartz or BK7 (borosilicate glass), metal such as Al may be used. The reflecting member 40 may also be formed using Si as the main material.

If the main material is a reflective material such as Al, the light reflecting surface 41B can be formed from the main material. Instead of forming the light reflecting surface 41B by using the main material, the outline of the reflecting member 40 may be formed with the main material, and the light reflecting surface 41B may be formed on the surface of the outline. In this case, the light reflecting surface 41B may be formed using, for example, a metal layer such as Ag or Al, or a dielectric multilayer film such as Ta₂O₅/SiO₂, TiO₂/SiO₂, Nb₂O₅/SiO₂.

The light reflecting surface 41B has a reflectance of 90% or more with respect to the peak wavelength of light irradiated onto the light reflecting surface 41B. Further, this reflectance may be 95% or more. Moreover, this reflectance may be 99% or more. The light reflectance is 100% or less, or less than 100%.

### Protective device 50

The protective device 50 has an upper surface, a lower surface, and one or plurality of lateral surfaces. The shape of the protective device 50 is a rectangular parallelepiped. It should be noted that the shape of the protective device 50 does not have to be a rectangular parallelepiped.

The protective device 50 serves to prevent a specific device (for example, a semiconductor laser element) from being destroyed by an excessive current flow. An example of the protective device 50 may be, for example, a Zener diode. As the Zener diode, one formed from Si may be used.

### Wire 60

The wire 60 is a linear conductive material with both ends serving as connecting portions. The connecting portions at both ends serve as bonding portions to other components. The wire 60 is used for electrical connection between two components. The wire 60 is, for example, a metal wire. As the metal, for example, gold, aluminum, silver, or copper may be used.

### Optical member 70

The optical member 70 has an upper surface 71A, a lower surface 71B, and one or plurality of lateral surfaces 71C. The optical member 70 imparts an optical effect to light incident on the optical member 70. The optical effect imparted to the light by the optical member 70 includes, for example, focusing, collimation, diffusion, polarization, diffraction, wavelength combining, light guiding, reflection, or wavelength conversion.

The optical member 70 has an optical action surface that imparts an optical effect. The upper surface 71A, lower surface 71B, or lateral surface 71C can serve as the optical action surface. Alternatively, the optical action surface may be provided at a location different from the upper surface 71A, lower surface 71B, and lateral surface 71C. For example, the optical action surface may be formed inside the optical member 70, rather than on its surface.

The optical member 70 may have one or plurality of lens surfaces 71D. The lens surface 71D is the optical action surface of the optical member 70. It should be noted that the optical member 70 having the lens surface 71D may be referred to as a lens member. Light exiting from the optical member 70 through the lens surface 71D is subjected to an optical effect such as focusing, diffusion, or collimation by the optical member 70. For example, the optical member 70 is a collimator lens through which light incident on the optical member 70 exits as collimated light.

The one or each lens surface 71D is provided on the upper surface 71A side. It should be noted that the lens surface 71D may be provided on the lower surface 71B side. The upper surface 71A and lower surface 71B are flat surfaces. The one or each lens surface 71D intersects with the upper surface 71A. In a top view, the one or each lens surface 71D is surrounded by the upper surface 71A.

In a top view, the outer shape of the optical member 70 is rectangular. It should be noted that the outer shape of the optical member 70 in a top view does not have to be rectangular. The lower surface 71B is a flat surface. On the lower surface 71B side of the optical member 70, the lens surface 71D is not formed. The shape of the lower surface 71B is rectangular. It should be noted that the shape of the lower surface 71B does not have to be rectangular.

In the optical member 70, the portion overlapping with the lens surface 71D in a top view is referred to as the lens part 72A. In the optical member 70, the portion overlapping with the upper surface 71A in a top view is referred to as the non-lens part 72B. The lower surface 71B has a region forming the lower surface of the one or each lens part 72A and a region forming the lower surface of the non-lens part 72B.

The optical member 70 may have a plurality of lens surfaces 71D formed in a continuous row in one direction. In a top view, the direction in which the plurality of lens surfaces 71D are arranged is referred to as the connection direction of the lenses. In the illustrated optical member 70, the connection direction is the same direction as the X direction.

The plurality of lens surfaces 71D are formed so that the apexes of the respective lens surfaces 71D are arranged on a straight line. This virtual straight line connecting the apexes is parallel to the lower surface 71B of the optical member 70. Here, "parallel" includes a tolerance within ±5 degrees.

Some or all of the plurality of lens surfaces 71D may have the same curvature as two or more lens surfaces 71D. All of the plurality of lens surfaces 71D may have the same curvature.

The optical member 70 has light transmissivity. The optical member 70 has a transmittance of 80% or more with respect to the peak wavelength of light incident on the optical member 70. The optical member 70 may have a region with light transmissivity and a region without light transmissivity (hereinafter referred to as a non-light-transmissive region). In the non-light-transmissive region, the transmittance with respect to the peak wavelength of light incident on the optical member 70 is 50% or less. The optical member 70 may be formed using, for example, glass such as BK7.

### Next, the light emitting device will be described.

### Light Emitting Device 1

In the light emitting device, one or plurality of semiconductor laser elements 20 are bonded to one or plurality of submounts 30. One or each semiconductor laser element 20 is disposed on the wiring layer 33. The one or each semiconductor laser element 20 is disposed on the alloy region 34A. The one or each semiconductor laser element 20 is bonded to the submount 30 via the alloy layer 34.

A semiconductor laser element 20 can be disposed on the alloy layer 34 in a molten state to bond the semiconductor laser element 20 to the submount 30. The alloy layer 34 transitions to a molten state over time by placing the submount 30 on a heater and heating the submount 30. By setting the time from placing the submount 30 on the heater to placing the semiconductor laser element 20 on the submount 30, it is possible to control so that the semiconductor laser element 20 is disposed on the alloy layer 34 in the molten state.

The one or each semiconductor laser element 20 is disposed on the flat region 34B2. The one or each semiconductor laser element 20 does not overlap with the thinning region 34B1 formed on the second end 34D side in a top view. As a result, the semiconductor laser element 20 is more likely to be stably bonded to the submount 30.

The one or each semiconductor laser element 20 may be disposed such that the distance from the first end 34C of the alloy region 34A on which a corresponding one of the semiconductor laser elements 20 is disposed is 100 μm or less. Further, one or each semiconductor laser element 20 may be disposed such that the distance from the second end 34D of the alloy region 34A on which a corresponding one of the semiconductor laser elements 20 is disposed is 100 μm or less. As a result, the width of the alloy region 34A from the first end 34C to the second end 34D can be reduced, and the submount 30 can be made smaller. The size reduction of the submount 30 can also contribute to the size reduction of the light emitting device 1.

The shape of the wiring layer 33 changes before and after the semiconductor laser element 20 is bonded. The alloy layer 34 after the semiconductor laser element 20 is bonded has, in cross-section, a convex part 36 having a convex curved shape in the portion protruding between the semiconductor laser element 20 and the metal layer 32B1. In cross-section, the convex part 36 is formed in both the protruding portion between the first end 34C and the semiconductor laser element 20 (hereinafter referred to as the first protruding portion) and the protruding portion between the second end 34D and the semiconductor laser element 20 (hereinafter referred to as the second protruding portion).

FIGS. 21A to 21D show images of the state where the semiconductor laser element 20 is bonded to the submount 30 of the example. FIGS. 22A to 22D show images of the state where the semiconductor laser element 20 is bonded to the submount of the comparative example.

Comparing FIG. 21B and FIG. 21D, in the submount 30 of the example, the maximum thickness of the convex part 36 in the first protruding portion is greater than the maximum thickness of the convex part 36 in the second protruding portion. On the other hand, comparing FIG. 22B and FIG. 22D, the maximum thickness of the convex part 36 in the first protruding portion is less than the maximum thickness of the convex part 36 in the second protruding portion.

This is considered to be because, in the submount of the comparative example, the melting time is short, so hardening of the alloy layer proceeds from the second end, and the convex part of the molten alloy layer rides over the flat region onto the hardened state, making the maximum thickness of the second protruding portion larger. On the other hand, in the submount of the example, because both the first and second ends are maintained in a molten state when the semiconductor laser element 20 is bonded, the relationship in which the maximum thickness on the first end side is greater in the pre-bonding state is also reflected after bonding. That is, in a submount in which a thinning region is formed only on one side of both ends, in the case of a submount that achieves a stable bonding state, the maximum thickness of the first protruding portion can be greater than the maximum thickness of the second protruding portion after the bonding. The maximum thickness of the convex part 36 in the first protruding portion can be regarded as the maximum thickness of the first protruding portion. The maximum thickness of the convex part 36 in the second protruding portion can be regarded as the maximum thickness of the second protruding portion.

In the alloy layer 34 after the bonding, the difference between the maximum thickness of the first protruding portion and the maximum thickness of the second protruding portion can be 0.8 μm or more. Alternatively, this difference can be 1.5 μm or more. By adjusting the design thickness, the amount of alloy in the alloy layer 34 becomes greater than in the comparative example, and thus a relatively large height difference is more likely to occur.

FIGS. 23A and 23B are images confirming the bonding surface of the semiconductor laser element after it has been removed from the submount of the example to investigate the bonding condition when bonding the semiconductor laser element to the submount. This investigation is performed by heating the submount in an oven set at 320°C for a predetermined time, then bonding the semiconductor laser element to the submount, and then heating at about 300°C after the bonding and removing the semiconductor laser element from the submount with a jig. FIGS. 24A to 24D are images confirming the same above for the comparative example submount. In each figure, two semiconductor laser elements (two experimental samples) are disposed side by side.

As can be seen from FIGS. 24A to 24D, in the semiconductor laser element bonded to the submount of the comparative example, a bipolarization of the eutectic state occurs at the bonding surface. The bipolarized parts are indicated respectively by arrows A and B. In FIG. 24A, the time from the start of heating to when the semiconductor laser element is disposed is 2.0 seconds, in FIG. 24B this time is 3.5 seconds, in FIG. 24C this time is 6.0 seconds, and in FIG. 24D this time is 8.0 seconds, but in all cases, bipolarization of the eutectic state occurs.

On the other hand, as can be seen from FIGS. 23A and 23B, in the semiconductor laser element bonded to the submount of the example, bipolarization of the eutectic state does not occur at the bonding surface. In FIG. 23A, the time from the start of heating to when the semiconductor laser element is disposed is 6 seconds, and in FIG. 23B this time is 8 seconds, but in both cases, bipolarization of the eutectic state does not occur.

In the light emitting device 1, when the semiconductor laser element 20 bonded to the submount 30 is removed from the submount 30 using a jig, no bipolarization of the eutectic state of the alloy occurs at the bonding surface of the semiconductor laser element 20. Confirmation of the presence or absence of such bipolarization can serve as one method of confirming that the submount achieves a stable bonding state or that the light emitting device is one in which the semiconductor laser element is stably bonded to the submount. It should be noted that it is not always necessary to judge the stable state of bonding from the state of the bonding surface of the component (such as the semiconductor laser element) removed from the submount.

Whether a stable bonding state can be said to exist may also vary depending on the application and usage environment, and if there are other confirmation methods appropriate to each case, those methods may be adopted. In this case, even if bipolarization occurs in the above-described confirmation method, there may be cases where a bonding state is judged as stable by another confirmation method. Further, there may be applications in which it is not possible to confirm a stable bonding state by the confirmation of the presence or absence of bipolarization described above, but at least, it can be clearly said that the absence of bipolarization means a more stable bonding state than when bipolarization occurs. If the wiring layer 33 is disposed so that a thinning region is formed on only one side of both ends, and it is confirmed that bipolarization has not occurred in the confirmation of the presence or absence of bipolarization, it can be said that the submount achieves a stable bonding state.

One or plurality of semiconductor laser elements 20 are disposed in the internal space of the package 10. The one or plurality of semiconductor laser elements 20 are disposed on the base 11. The one or plurality of semiconductor laser elements 20 are disposed on the first upper surface 11A via the submount(s) 30.

In the light emitting device 1, one or plurality of semiconductor laser elements 20 may be composed of a plurality of semiconductor laser elements disposed in a row in one direction. Here, the direction in which the plurality of semiconductor laser elements are disposed is referred to as the first direction.

The one or plurality of submounts 30 may be composed of a plurality of submounts disposed in a row in one direction. Each of the plurality of semiconductor laser elements 20 is disposed on one of the submounts 30. The direction in which the plurality of submounts 30 are disposed is the same as the direction in which the plurality of semiconductor laser elements 20 are disposed. Therefore, the direction in which the plurality of submounts 30 are disposed may also be referred to as the first direction. In the illustrated light emitting device 1, one semiconductor laser element 20 is disposed on one submount 30.

In a top view, the plurality of submounts 30 are disposed so that the first side 31A1 of one of two adjacent submounts 30 faces the second side 31A2 of the other submount 30. Because the wiring layer 33 is positioned closer to one side of the first side 31A1 and the second side 31A2 of the submount 30, more semiconductor laser elements 20 can be disposed on the first upper surface 11A.

The interval between adjacent submounts 30 can be 300 μm or less. The interval between adjacent semiconductor laser elements 20 can be 1000 μm or less. As a result, more semiconductor laser elements can be disposed in a row.

The one or plurality of semiconductor laser elements 20 emit light in a predetermined direction. Here, this predetermined direction is referred to as the second direction. Each of the plurality of semiconductor laser elements 20 emits light in the same direction. The plurality of semiconductor laser elements 20 emits light in a direction perpendicular to the first direction. In the illustrated light emitting device 1, light is emitted in the Y direction from the one or plurality of semiconductor laser elements 20.

In the light emitting device 1, the one or plurality of reflecting members 40 are disposed in the internal space of the package 10. The one or plurality of reflecting members 40 are disposed on the base 11. The one or plurality of reflecting members 40 are disposed at positions separated from the one or plurality of semiconductor laser elements 20 in the second direction.

The one or plurality of reflecting members 40 reflect light emitted from the one or plurality of semiconductor laser elements 20. Light emitted from the one or plurality of semiconductor laser elements 20 exits upward from the upper surface 14A of the package 10. Light is reflected upward by the light reflecting surface 41B of each reflecting member 40.

In the light emitting device 1, the one or plurality of protective devices 50 are disposed in the internal space of the package 10. The one or plurality of protective devices 50 are bonded to the package 10. The one or plurality of protective devices 50 are bonded to the frame part 11N. One or plurality of protective devices 50 are disposed on the upper surface 11G. By not disposing the protective device 50 on the submount 30, the submount 30 can be made smaller.

In the light emitting device 1, a plurality of wires 60 are provided for electrically connecting the one or plurality of semiconductor laser elements 20 to the package 10. The plurality of wires 60 include one or plurality of first wires 60A that are bonded to the submount 30.

The one or plurality of first wires 60A bond one end to one of two adjacent submounts 30, and bond the other end to the semiconductor laser element 20 disposed on the other submount 30. In a top view, the one or plurality of first wires 60A bond one end to the submount 30 between the second end 34D and the second side 31A2. As a result, the length of the first wire 60A can be reduced, contributing to a reduction in wiring resistance.

One or plurality of semiconductor laser elements 20 may emit light with a peak emission wavelength of 605 nm or more. The one or plurality of semiconductor laser elements 20 may include semiconductors such as InAlGaP-based, GaInP-based, or GaAs-based semiconductors such as GaAs or AlGaAs. Such semiconductor laser elements 20 have relatively low temperature characteristics, so a structure in which the semiconductor laser element 20 does not become as high temperature as possible is preferable. With such semiconductor laser elements 20, achieving stable bonding also contributes to improved heat dissipation and can have a positive effect on the output characteristics of the semiconductor laser element 20. In other words, by achieving stable bonding, the output characteristics of the light emitting device 1 can be improved.

In the light emitting device 1, the optical member 70 is bonded to the package 10. The optical member 70 is bonded to the upper surface 14A. Light emitted from the package 10 is incident on the optical action surface 71D of the optical member 70. The light to which the optical effect is imparted exits the optical member 70. The light exiting the optical member 70 can be light emitted from the light emitting device 1.

In the illustrated light emitting device 1, the non-lens part 72B of the optical member 70 and the package 10 are bonded via an adhesive. Light emitted from the package 10 passes through the lens part 72A without passing through this adhesive. Light incident on the optical member 70 passes through the one or plurality of lens surfaces 71D, becomes collimated light, and exits the optical member 70.

Although the embodiments according to the present invention is described as above, the submount and light emitting device according to the present invention are not strictly limited to the submount and light emitting device of the embodiment. That is, the present invention can be achieved without being limited to the outer shape or structure of the submount and light emitting device disclosed by the embodiment. The present invention can be applied without requiring all components. For example, if some components of the light emitting device disclosed by the embodiment are not described in the claims, it is specified that the invention described in the claims is applicable, allowing for design freedom by those skilled in the art, such as substitution, omission, shape modification, or material change for those components.

The sub-mount and the light-emitting device described in the embodiments can be used in projectors. In other words, the projector can be considered as one application form to which the present invention is applied. The present invention is not limited to this, and can be utilized in various application forms such as projectors, lighting, exposure devices, automotive headlights, head-mounted displays, and backlights for other displays.

What is claimed is:

1. A submount comprising:
a substrate;
a metal layer provided on an upper surface side of the substrate; and
an alloy layer provided on the metal layer, wherein
an upper surface of the substrate has a first side and a second side each constituting a part of an outer edge of the substrate in a top view, the second side being opposite the first side,
the alloy layer forms at least one continuous alloy region in the top view,
the at least one alloy region is provided in at least a part of an area within less than 100 μm from the first side of the substrate, and in a part of an area at a distance of 100 μm or more from the first side of the substrate, and is not provided in an area within 100 μm from a line segment of the second side, the line segment having a length of at least 20% or more of a total length of the second side,
the alloy layer has
a first end adjacent to the first side of the substrate, and
a second end on an opposite side of the first end,
in a cross-sectional view taken along a plane passing through the first side of the substrate, the second side of the substrate, and the alloy region in an area where the alloy region is not provided within 100 μm from the line segment of the second side, a thickness of the alloy layer at the first end and its vicinity is greater than a thickness of the alloy layer at the second end and its vicinity, and
the thickness of the alloy layer at the second end and its vicinity is 1.5 μm or more.

2. The submount according to claim 1, wherein
in the cross-sectional view, the alloy region has
on a second side, a thinning region where the thickness of the alloy layer decreases toward the second end, and
on a first end side, a region where the thickness of the alloy layer decreases toward the first end, but no region equivalent to the thinning region formed on the second side is formed.

3. The submount according to claim 2, wherein
a difference between a maximum thickness and a minimum thickness in the thinning region is 0.7 μm or more.

4. The submount according to claim 2, wherein
a maximum thickness of the alloy layer is 3.5 μm or less.

5. The submount according to claim 2, wherein
in the cross-sectional view, the alloy layer has a thickened region on the second end side, between the thinning region and the second end, and
a thickness of the thickened region is greater than a minimum thickness of the thinning region.

6. The submount according to claim 1, wherein
the alloy layer is made of AuSn.

7. A method for manufacturing a light emitting device comprising: providing the submount according to claim 1; and
bonding a semiconductor laser element to the submount by disposing a semiconductor laser element on the alloy layer in a molten state.

8. A light emitting device comprising:
one or plurality of submounts each having an upper surface and a lower surface;
one or plurality of semiconductor laser elements bonded to the one or more of submounts; and
a base on which the one or plurality of submounts are mounted, wherein
each of the one or plurality of submounts includes
a substrate,
a metal layer provided on the substrate, and
an alloy layer provided on the metal layer,
the upper surface of each of the one or plurality of submounts has a first side and a second side, each constituting a part of an outer edge of the one or plurality of submounts in a top view, the second side being opposite the first side,
the alloy layer forms at least one continuous alloy region in the top view,
the at least one alloy region is provided in at least a part of an area within less than 100 μm from the first side, and in a part of an area at a distance of 100 μm or more from the first side, and is not provided in an area within 100 μm from a line segment the second side, the line segment having a length of at least 20% or more of a total length of the second side,
the one or plurality of semiconductor laser elements are disposed on the alloy region and bonded to the one or plurality of submounts via the alloy layer,
the alloy layer has
a first end adjacent to the first side,
a second end on an opposite side of the first end,
a first protruding portion positioned between the first end and a corresponding one of the one or plurality of semiconductor laser elements, and
a second protruding portion positioned between the second end and the corresponding one of the one or plurality of semiconductor laser element,
in a cross-sectional view taken along a plane passing through the first side, the second side, and the alloy region in an area where the alloy region is not provided within 100 μm from the line segment of the second side, a maximum thickness of the first protruding portion is greater than a maximum thickness of the second protruding portion.

9. The light emitting device according to claim 8, wherein
a difference between the maximum thickness of the first protruding portion and the maximum thickness of the second protruding portion is 0.8 μm or more.

10. The light emitting device according to claim 8, wherein
when the one or plurality of semiconductor laser elements bonded to the one or pluralityof submounts are heated at about 300°C and removed from the one or plurality of submounts by a jig, bipolarization of an eutectic state of the alloy layer does not occur at a bonding surface of a corresponding one of the one or plurality of semiconductor laser elements.

11. The light emitting device according to claim 8, wherein
the one or plurality of submounts include a plurality of submounts arranged in a first direction,
the one or plurality of semiconductor laser elements include a plurality of semiconductor laser elements respectively disposed on the plurality of submounts,
the plurality of submounts are disposed such that the first side of one of two adjacent ones of the plurality of submounts faces the second side of other one of the two adjacent ones of the plurality of submounts in the top view, and
each of the plurality of semiconductor laser elements is configured to emit light in a direction perpendicular to the first direction.

12. The light emitting device according to claim 8, wherein
the alloy layer is made of AuSn.
